(19) United States
(12) Patent Application Publication
(10) Pub. No.: US 2017/0372975 A1
(43) Pub. Date: Dec. 28, 2017

(54) INLINE KERF PROBING OF PASSIVE DEVICES

(71) Applicant: QUALCOMM Incorporated, San Diego, CA (US)

(72) Inventors: Daeik Daniel KIM, Del Mar, CA (US); David Francis BERDY, San Diego, CA (US); Changhan Hobie YUN, San Diego, CA (US); Mario Francisco VELEZ, San Diego, CA (US); Chengjie ZUO, San Diego, CA (US); Jonghae KIM, San Diego, CA (US)

(21) Appl. No.: 15/191,062

(22) Filed: Jun. 23, 2016

(51) Int. Cl. H01L 21/66; H01L 23/544; H01L 23/66

(52) U.S. Cl. CPC H01L 22/32; H01L 23/66; H01L 23/544; H01L 2223/6672; H01L 2223/5446

(57) ABSTRACT

A radio frequency (RF) integrated circuit may include a die having passive components including at least one pair of capacitors covered by a first dielectric layer supported by the die. The RF integrated circuit may also include an inline pad structure coupled to the at least one pair of capacitors proximate an edge of the die. The inline pad structure may include a first portion and a second portion extending into a dicing street toward the edge of the die and covered by at least a second dielectric layer.

### TECHNICAL FIELD

The present disclosure generally relates to integrated circuits (ICs). More specifically, the present disclosure relates to inline Kerf probing of passive devices.

### BACKGROUND

The process flow for semiconductor fabrication of integrated circuits (ICs) may include front-end-of-line (FEOL), middle-of-line (MOL), and back-end-of-line (BEOL) processes. The front-end-of-line process may include wafer preparation, isolation, well formation, gate patterning, spacer, extension and source/drain implantation, silicide formation, and dual stress liner formation. The middle-of-line process may include gate contact formation. Middle-of-line layers may include, but are not limited to, middle-of-line contacts, vias or other layers within close proximity to the semiconductor device transistors or other active devices. The back-end-of-line process may include a series of wafer processing steps for interconnecting the semiconductor devices created during the front-end-of-line and middle-of-line processes.

Successful fabrication of modern semiconductor chip products involves interplay between the materials and the processes employed. A challenge of maintaining a small feature size applies to passive on glass (POG) technology, where high-performance components such as inductors and capacitors are built upon a highly insulative substrate that may also have a very low loss.

Passive on glass devices involve high-performance inductor and capacitor components that have a variety of advantages over other technologies, such as surface mount technology or multi-layer ceramic chips that are commonly used in the fabrication of mobile radio frequency (RF) chip designs (e.g., mobile RF transceivers). The design complexity of mobile RF transceivers is complicated by the migration to a deep sub-micron process node due to cost and power consumption considerations. Spacing considerations also affect mobile RF transceiver design at the deep sub-micron process node.

Mobile transceiver designs are tested before products are completed. The passive devices in the transceivers can be tested individually as part of the testing. Conventional inline testing of passive devices of mobile RF transceivers may damage these passive devices due to high pressure applied to the passive devices during probing. An alternative testing procedure, including extended probe pads, consumes additional area, increasing the overall die size. There is a need for lowering the testing cost without increasing die area.

### SUMMARY

A radio frequency (RF) integrated circuit may include a die having passive components including at least one pair of capacitors covered by a first dielectric layer supported by the die. The RF integrated circuit may also include an inline pad structure coupled to the at least one pair of capacitors proximate an edge of the die. The inline pad structure may include a first portion and a second portion extending into a dicing street toward the edge of the die and covered by at least a second dielectric layer.

A radio frequency (RF) module may include a passive die having a plurality of passive components including at least one pair of capacitors covered by a first dielectric layer supported by the passive die. The RF module may also include an inline pad structure coupled to the at least one pair of capacitors proximate an edge of the passive die. The inline pad structure may include a first portion and a second portion extending into a dicing street toward the edge of the passive die and covered by at least a second dielectric layer. The RF module may further include an active die coupled to the passive die.

A method for making and inline testing a radio frequency (RF) integrated circuit on a die having an edge adjacent to a dicing street may include fabricating a pair of capacitors on the die. The method may also include testing the pair of capacitors by applying a signal to exposed first and second test pad structures extending into the dicing street toward the edge of the die. The method may further include covering the exposed first and second test pad structures after applying the signal.

A radio frequency (RF) integrated circuit may include a die having passive components including at least one pair of capacitors covered by a first dielectric layer supported by the die. An RF integrated circuit may also include an inline pad structure coupled to the at least one pair of capacitors proximate an edge of the die. The inline pad structure may include means for extending into a dicing street toward the edge of the die and covered by at least a second dielectric layer.

This has outlined, rather broadly, the features and technical advantages of the present disclosure in order that the detailed description that follows may be better understood. Additional features and advantages of the disclosure will be described below. It should be appreciated by those skilled in the art that this disclosure may be readily utilized as a basis for modifying or designing other structures for carrying out the same purposes of the present disclosure. It should also be realized by those skilled in the art that such equivalent constructions do not depart from the teachings of the disclosure as set forth in the appended claims. The novel features, which are believed to be characteristic of the disclosure, both as to its organization and method of operation, together with further objects and advantages, will be better understood from the following description when considered in connection with the accompanying figures. It is to be expressly understood, however, that each of the figures is provided for the purpose of illustration and description only and is not intended as a definition of the limits of the present disclosure.

### BRIEF DESCRIPTION OF THE DRAWINGS

For a more complete understanding of the present disclosure, reference is now made to the following description taken in conjunction with the accompanying drawings.

FIG. 1 illustrates a perspective view of a semiconductor wafer in an aspect of the present disclosure.

FIG. 2A illustrates a die of a radio frequency integrated circuit after fabrication of a multiplexer including passive on glass devices according to aspects of the present disclosure.

FIG. 2B is a schematic diagram of the multiplexer fabricated on the die of FIG. 2A according to aspects of the present disclosure.

FIG. 2C provides a zoomed in view of a corner of the die of FIG. 2A according to an aspect of the present disclosure.

FIGS. 3A and 3B show a cross section view and an overhead view of a capacitor coupled to an inline pad structure at an edge of a die and extending into a dicing street toward the edge of the die according to an aspect of the present disclosure.

FIGS. 4A and 4B show a cross section view and an overhead view of a capacitor coupled to an inline pad structure at an edge of a die and extending into a dicing street toward the edge of the die according to another aspect of the present disclosure.

FIG. 5 is a process flow diagram illustrating a method of making and inline testing of an RF integrated circuit on a die having an edge adjacent to a dicing street according to aspects of the present disclosure.

FIG. 6 is a schematic diagram of a radio frequency (RF) front end (RFFE) module employing passive devices according to an aspect of the present disclosure.

FIG. 7 is a schematic diagram of a WiFi module and a radio frequency (RF) front end (RFFE) module employing passive devices for a chipset to provide carrier aggregation according to aspects of the present disclosure.

FIG. 8 is a block diagram showing an exemplary wireless communication system in which a configuration of the disclosure may be advantageously employed.

FIG. 9 is a block diagram illustrating a design workstation used for circuit, layout, and logic design of a semiconductor component according to one configuration.

### DETAILED DESCRIPTION

The detailed description set forth below, in connection with the appended drawings, is intended as a description of various configurations and is not intended to represent the only configurations in which the concepts described herein may be practiced. The detailed description includes specific details for the purpose of providing a thorough understanding of the various concepts. It will be apparent to those skilled in the art, however, that these concepts may be practiced without these specific details. In some instances, well-known structures and components are shown in block diagram form in order to avoid obscuring such concepts. As described herein, the use of the term “and/or” is intended to represent an “inclusive OR”, and the use of the term “or” is intended to represent an “exclusive OR”.

Passive on glass devices involve high-performance inductor and capacitor components that have a variety of advantages over other technologies, such as surface mount technology or multi-layer ceramic chips that are commonly used in the fabrication of mobile radio frequency (RF) chip designs (e.g., mobile RF transceivers). Conventional inline testing of these passive devices of mobile RF transceivers may damage the passive devices due to high pressure applied to the passive devices during probing.

Various aspects of the disclosure provide techniques for inline Kerf probing of passive devices. The process flow for semiconductor fabrication and testing of an RF integrated circuit with passive devices may include front-end-of-line (FEOL) processes, middle-of-line (MOL) processes, and back-end-of-line (BEOL) processes. It will be understood that the term “layer” includes film and is not to be construed as indicating a vertical or horizontal thickness unless otherwise stated. As described herein, the term “substrate” may refer to a substrate of a diced wafer or may refer to a substrate of a wafer that is not diced. Similarly, the terms chip and die may be used interchangeably unless such interchanging would tax credulity.

As described herein, the back-end-of-line interconnect layers may refer to the conductive interconnect layers (e.g., metal one (M1), metal two (M2), metal three (M3), metal four (M4), etc.) for electrically coupling to front-end-of-line active devices of an integrated circuit. The back-end-of-line interconnect layers may electrically couple to middle-of-line interconnect layers for, for example, connecting M1 to an oxide diffusion (OD) layer of an integrated circuit. A back-end-of-line first via (V2) may connect M2 to M3 or others of the back-end-of-line interconnect layers.

Various aspects of the disclosure provide techniques for inline testing of passive devices (e.g., metal-insulator-metal (MIM) capacitors) at a die area boundary at reduced cost. Generally, once fabrication of integrated circuits on a substrate is complete, the substrate is divided along dicing lines (e.g., a dicing street). The dicing lines indicate where the substrate is to be broken apart or separated into pieces. The dicing lines may define the outline of the various integrated circuits that have been fabricated on the substrate. Once the dicing lines are defined, the substrate may be sawn or otherwise separated into pieces to form the die. The die area boundary may include a non-functional boundary area according to a groove created by a dicing saw blade (Kerf) along the dicing street. Alternatively, laser dicing may be performed to provide separation between the die and a Kerf area at the edge of the die without material loss.

Testing of passive devices at the die area boundary (e.g., a Kerf area) is generally difficult as these devices are covered by passivation layers due to the circuit topology. Conventional inline testing may damage these passive devices due to high pressure applied to the passive device dielectric during probing. For example, individual device inline testing may damage the dielectric insulator of metal-insulator-metal (MIM) capacitors due to high pressure applied to the capacitors during probing. In addition, providing extended probe pads for testing involves additional die area, which increases cost. Alternatively, full radio frequency (RF) testing is complex, which makes such testing both costly and time consuming.

In one aspect of the present disclosure, the Kerf area is used to provide inline testing of the passive devices at a die area boundary. The testing is enabled by fabricating an inline pad structure coupled to a passive device (e.g., a MIM capacitor) covered by a first dielectric layer near an edge of a passive substrate supporting the passive device. In this arrangement, the inline pad structure includes a first portion and a second portion extending toward the edge of the die and proximate a Kerf area along a dicing street at the die edge. The inline pad structure is covered by at least a second dielectric layer following testing.

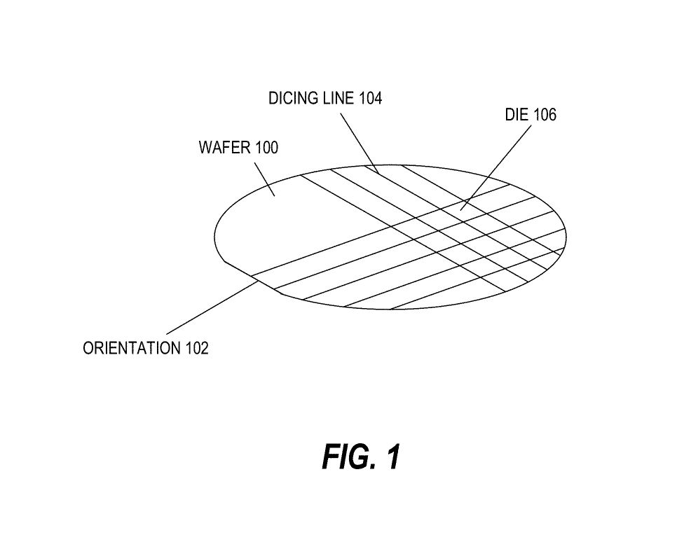

FIG. 1 illustrates a perspective view of a wafer in an aspect of the present disclosure. A wafer 100 may be a semiconductor wafer, or may be a substrate material with one or more layers of material on a surface of the wafer 100. The wafer 100 may be a compound material, such as gallium arsenide (GaAs) or gallium nitride (GaN), a ternary material such as indium gallium arsenide (InGaAs), quaternary materials, silicon, quartz, glass, or any material that can be a substrate material. Although many of the materials may be crystalline in nature, polycrystalline or amorphous materials may also be used for the wafer 100. For example, various options for the substrate include a glass substrate, a semiconductor substrate, a core laminate substrate, a coreless substrate, a printed circuit board (PCB) substrate, or other like substrates.

The wafer 100, or layers that are coupled to the wafer 100, may be supplied with materials that enable formation of different types of electronic devices in or on the wafer 100. In addition, the wafer 100 may have an orientation 102 that indicates the crystalline orientation of the wafer 100. The orientation 102 may be a flat edge of the wafer 100 as shown in FIG. 1, or may be a notch or other indicia to illustrate the crystalline orientation of the wafer 100. The orientation 102 may indicate the Miller Indices for the planes of the crystal lattice in the wafer 100, assuming a semiconductor wafer.

Once the wafer 100 has been processed as desired, the wafer 100 is divided up along dicing lines 104. For example, once fabrication of integrated circuits on the wafer 100 is complete, the wafer 100 is divided up along the dicing lines 104, which may be referred to herein as “dicing streets.” The dicing lines 104 indicate where the wafer 100 is to be broken apart or separated into pieces. The dicing lines 104 may define the outline of the various integrated circuits that have been fabricated on the wafer 100.

Once the dicing lines 104 are defined, the wafer 100 may be sawn or otherwise separated into pieces to form the die 106. Each of the die 106 may be an integrated circuit with many devices or may be a single electronic device. The physical size of the die 106, which may also be referred to as a chip or a semiconductor chip, depends at least in part on the ability to separate the wafer 100 into certain sizes, as well as the number of individual devices that the die 106 is designed to contain.

Once the wafer 100 has been separated into one or more die 106, the die 106 may be mounted into packaging to allow access to the devices and/or integrated circuits fabricated on the die 106. Packaging may include single in-line packaging, dual in-line packaging, motherboard packaging, flip-chip packaging, indium dot/bump packaging, or other types of devices that provide access to the die 106. The die 106 may also be directly accessed through wire bonding, probes, or other connections without mounting the die 106 into a separate package.

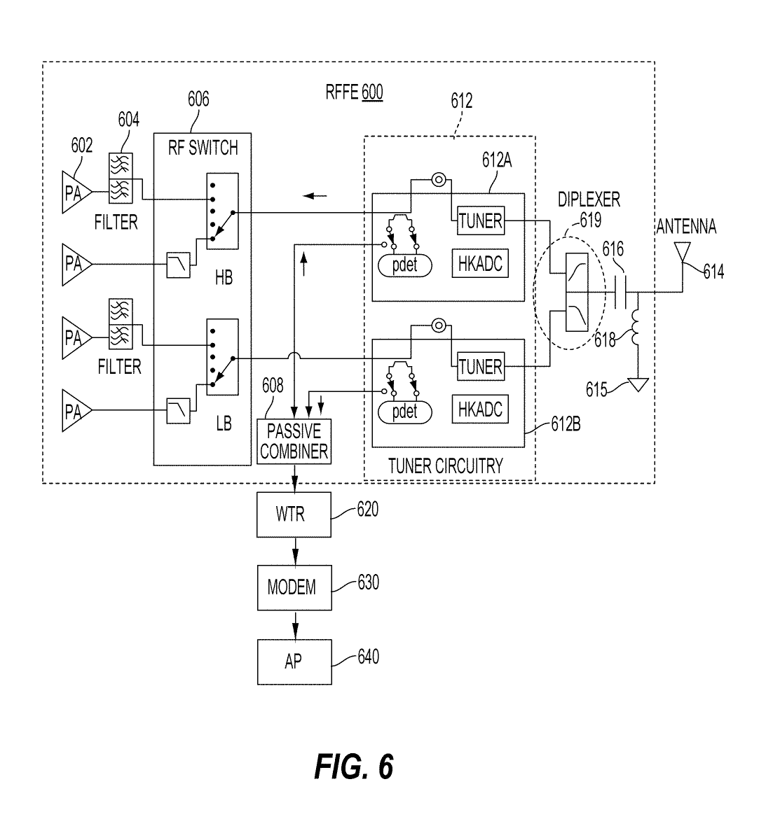

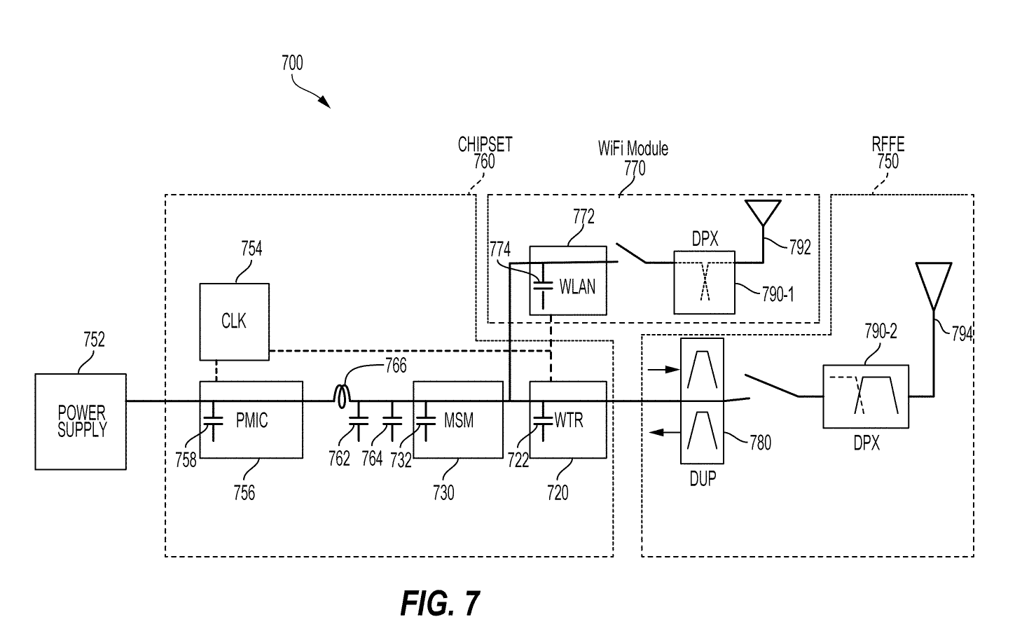

Inductors, as well as other passive devices such as capacitors, may be formed on the die. The die may be an active die or a passive die. In addition, an active die may be stacked on a passive die. Alternatively, the active die is provided in a side by side arrangement on a package substrate or a lead frame. These components may be used to form a filter, a diplexer, a triplexer, a low pass filter, and/or a notch filter, or other like passive circuit elements useful in the formation of radio frequency (RF) front end modules, for example, as shown in FIGS. 6 and 7, using passive on glass technology.

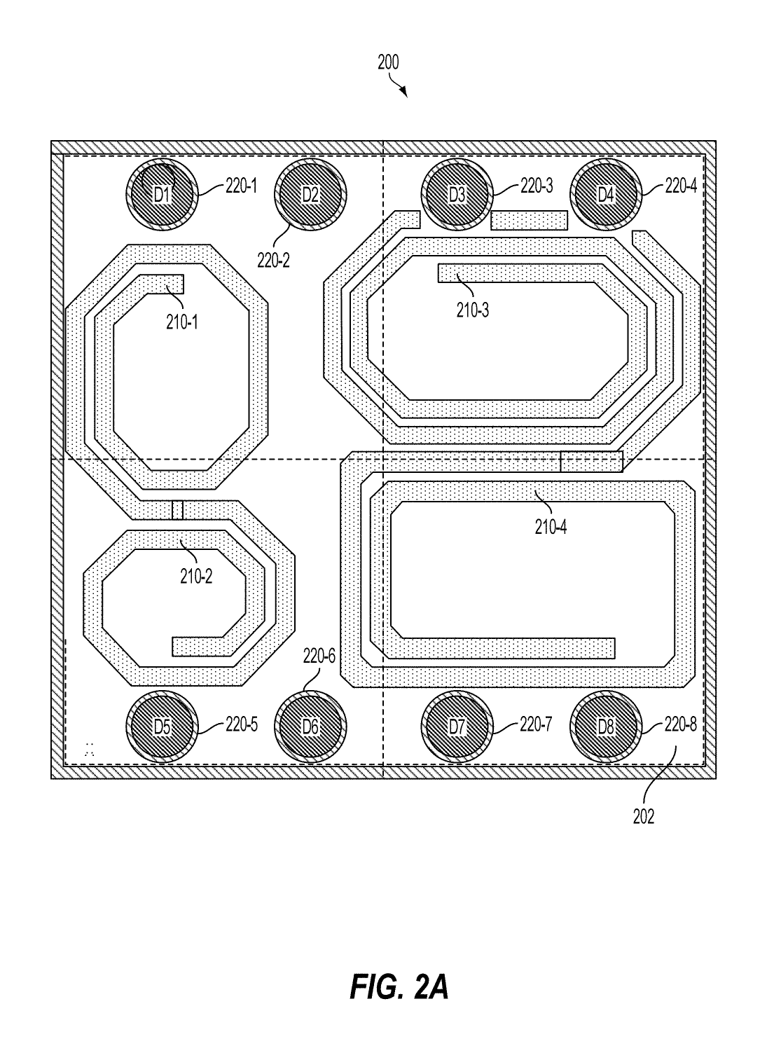

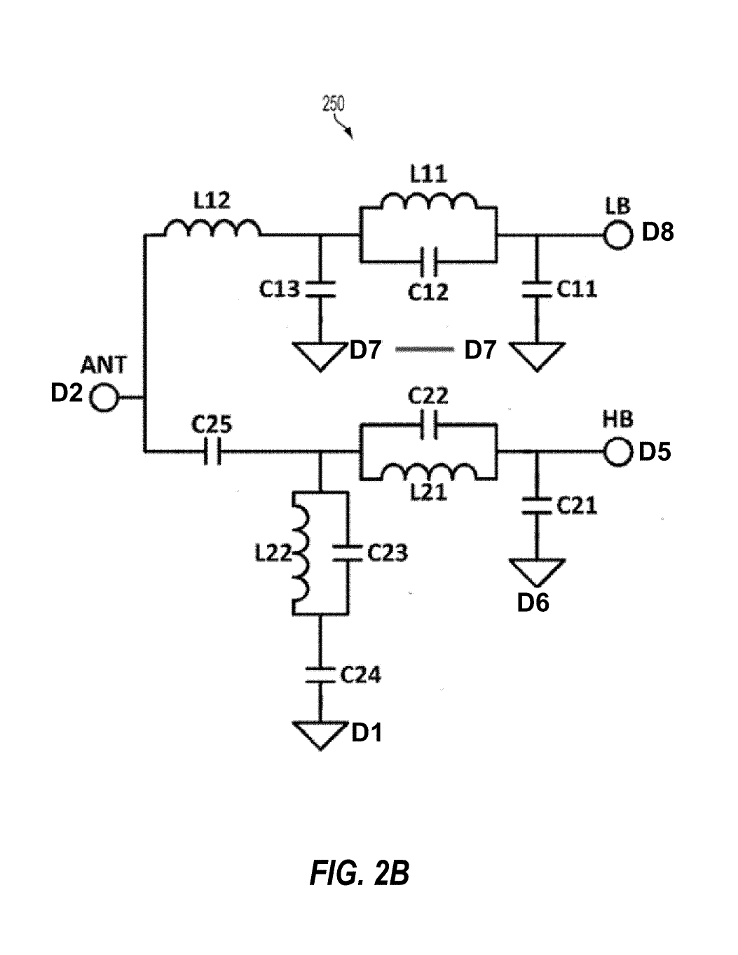

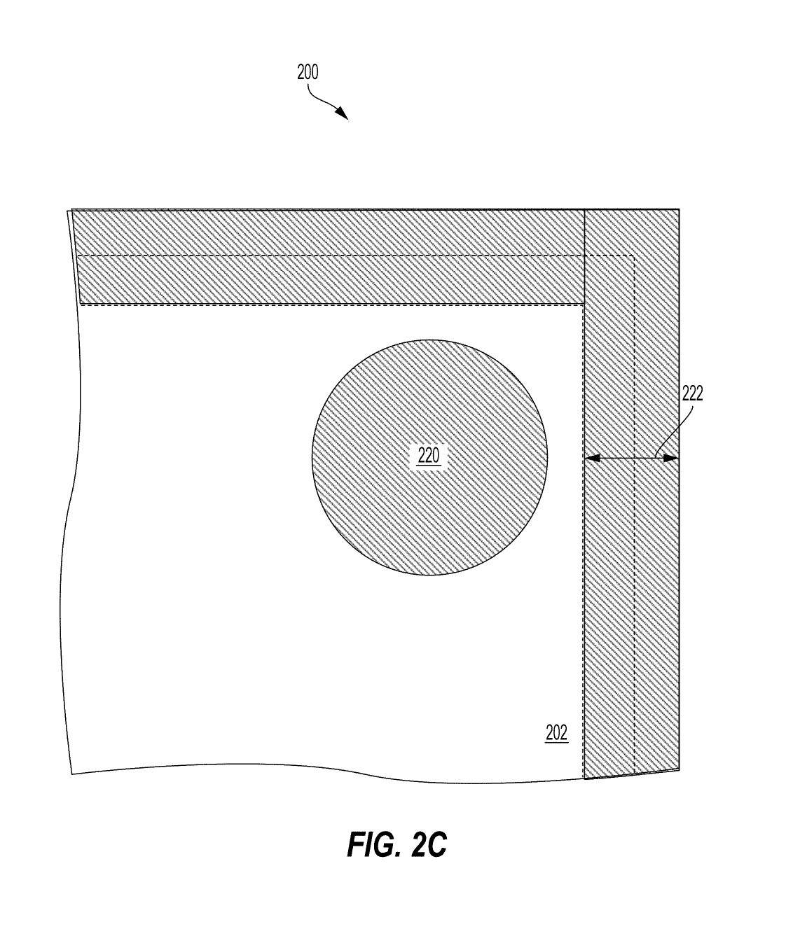

FIG. 2A illustrates a die 200 of a passive substrate 202 after fabrication of passive on glass (POG) devices on the passive substrate 202 to form a diplexer 250 (FIG. 2B) according to aspects of the present disclosure. The die 200 includes passive on glass devices, inductor components 210 (210-1, 210-2, 210-3, and 210-4) and capacitor components (not shown), which may be high-performance components that have a variety of advantages over other technologies. These other technologies may include surface mount technology and multi-layer ceramic chips that are commonly used in the fabrication of mobile radio frequency (RF) chip designs (e.g., mobile RF transceivers).

In this arrangement, the die 200 includes input/output (I/O) pads 220 (220-1, 220-2, 220-3, 220-4, 220-5, 220-6, 220-7, and 220-8) to access the passive devices including the inductor components 210. The pads 220 are arranged proximate to a die area boundary. The pads may be fabricated using surface mount technology (SMT). The SMT assembly process generally includes two types of land patterns for the surface mount packages. The first type of land patterns are non-solder mask defined (NSMD) pads. These pads generally have a wider mask opening than metal pads. The second type of land patterns are solder mask defined (SMD) pads. These pads have a reduced solder mask opening compared to metal pads.

FIG. 2B illustrates a schematic diagram of a diplexer 250, as partially shown in FIG. 2A, according to aspects of the present disclosure. In this arrangement, the diplexer 250 includes an antenna pad D2 (e.g., 220-2 in FIG. 2A). The diplexer 250 also includes a low band (LB) path coupled to an LB pad D8 (e.g., 220-8 in FIG. 2A), and a high band (HB) path coupled to an HB pad D5 (e.g., 220-5 in FIG. 2A). The LB path includes an input inductor L12 coupled between the antenna pad D2 and an input capacitor C13. The input capacitor C13 is coupled in series with a parallel coupled inductor L11 and a resonator capacitor C12 as well as an output capacitor C11 coupled to the LB pad D8. The input capacitor C13 and the output capacitor C11 are coupled to a pad D7 (e.g., 220-7 in FIG. 2A).

In this configuration, the HB path includes an input capacitor C25 coupled between the antenna pad D2, a parallel coupled inductor L21 and a resonator capacitor C22, and a parallel coupled inductor L22 and a resonator capacitor C23, coupled to a capacitor C24. The capacitor C24 is coupled to a pad D1 (e.g., 220-1 in FIG. 2A). An output capacitor C21 is coupled between the parallel coupled inductor L21 and the resonator capacitor C22, an I/O pad D6 (e.g., 220-6 in FIG. 2A), and the HB pad D5.

Testing of the diplexer 250 may be performed using a direct current (DC) test. Unfortunately, the DC test only provides partial test coverage of the diplexer 250. For example, the DC test does not enable testing of the resonator capacitor C12, the resonator capacitor C22, or the resonator capacitor C23 because these resonator capacitors are shorted by their parallel coupled inductors (e.g., L11, L21, and L22). Furthermore, conventional inline testing of the resonator capacitors may damage these passive devices due to high pressure applied to the capacitor dielectric during probing.

One possibility for verifying operation of the resonator capacitors is testing along the perimeter of the die 200 (FIG. 2A). Unfortunately, testing of passive devices at the die area boundary (e.g., a Kerf area) is difficult as these devices are generally covered by passivation layers due to the circuit topology. Extended probe pads may be used to test the passive device; however, providing extended probe pads for testing consumes additional die area, which increases cost. Alternatively, full radio frequency (RF) testing is complex, which makes such testing both costly and time consuming.

In one aspect of the present disclosure, the Kerf area is used for inline testing of the passive devices at the die area boundary. The testing is supported by fabrication of an inline pad structure that is coupled to a passive device (e.g., a MIM capacitor) covered by a first dielectric layer near an edge of a die including the passive device. In this arrangement, the inline pad structure includes a first portion and a second portion extending toward the edge of the die, proximate to the Kerf area at the die area boundary. The inline pad structure may be covered by at least a second dielectric layer after testing.

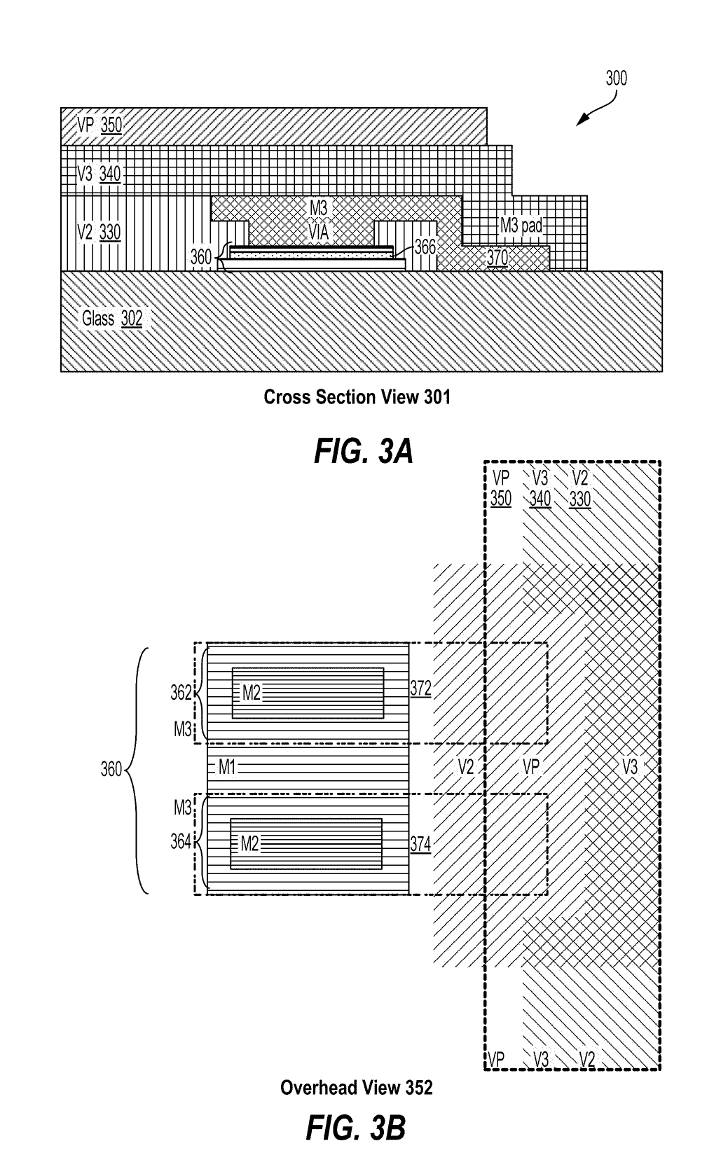

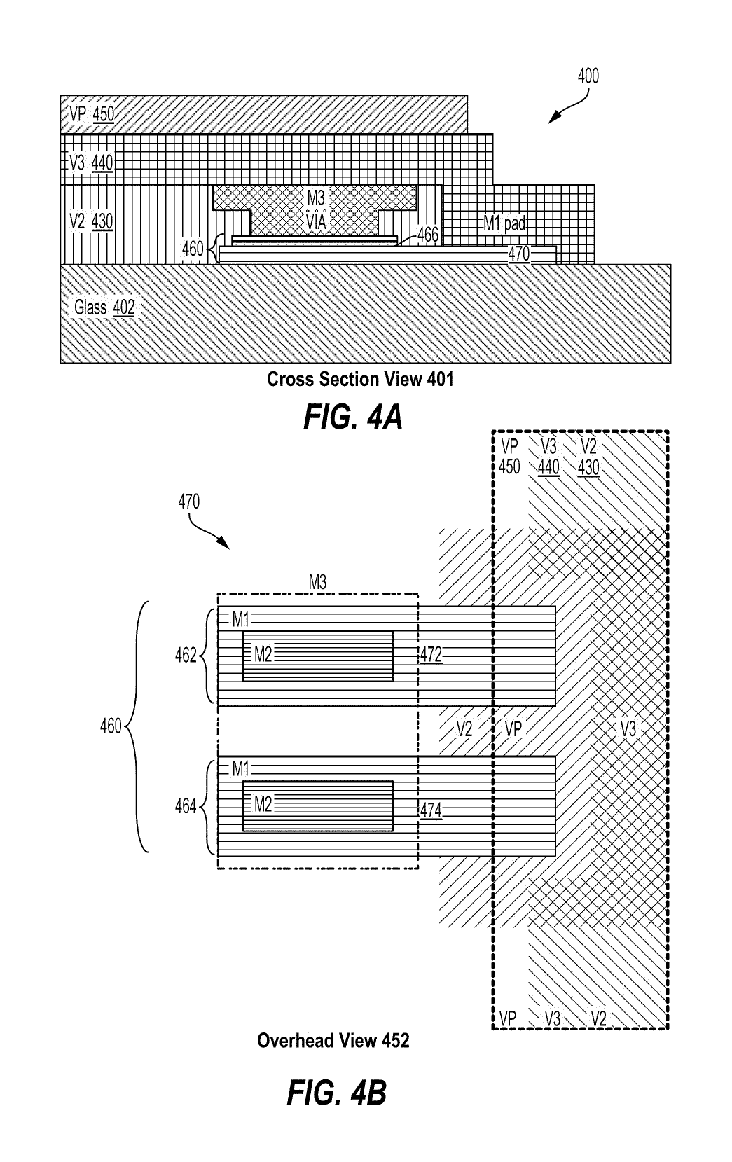

This arrangement of an inline pad structure proximate to the die Kerf area enables testing of the resonator capacitors (e.g., C12, C22, C23) at a lower conductive interconnect layer before they are shorted by the inductors (e.g., L11, L21, L22). The inline pad structures may be open at a lower conductive interconnect level (e.g., M1 or M3) for testing and covered with a passivation layer after testing, for example, as shown in FIGS. 3A to 4B. Once the integrity of the resonator capacitors (e.g., C12, C22, C23) is verified, the inductors (e.g., L11, L21, L22) are formed at an upped conductive interconnect level (e.g., M4, M5, etc.)

As noted above, a substrate used to form the die 200 may be a passive substrate panel formed by dicing a glass substrate panel along the dicing lines, which may be referred to herein as “dicing streets.” The dicing lines indicate where the glass panel substrate is to be broken apart or separated into pieces. The dicing lines may also define the outline of the various RF circuits that are fabricated on the glass panel substrate. This dicing process may be performed using a laser dicing process that involves a scribing and cracking process along the dicing street without material loss. Laser dicing may be distinguished from the dicing of silicon, which involves material loss due to grinding of, for example, a saw blade along the dicing street.

FIG. 2C provides a zoomed in view of a corner of the die 200 including a pad 220 on a passive substrate 202 of FIG. 2A. A die area boundary near an edge of the passive substrate 202 may include a non-functional boundary area according to a groove or scribe (e.g., a portion of the dicing street 222) created by dicing to form the die 200. In one aspect of the present disclosure, this portion of the dicing street is referred to as a Kerf area that is used for inline testing of the passive devices at the die area boundary. In this arrangement, an inline pad structure, including a first portion and a second portion extending toward the edge of the passive substrate 202 and proximate to the dicing street 222, is used to test the passive devices of the die 200.

FIGS. 3A and 3B show a cross section view and an overhead view of a capacitor coupled to an inline pad structure at an edge of a die and extending into a dicing street toward the edge of the die, according to an aspect of the present disclosure.

As shown in the cross section view 301 of FIG. 3A, a radio frequency (RF) integrated circuit is composed of a die 300 including a glass substrate 302, supporting multiple passivation (e.g., dielectric) layers and a capacitor 360. As shown in the cross section view 301, a first passivation layer 350 (VP) is supported by a second passivation layer 340 (V3) that is supported by a third passivation layer 330 (V2). The die 300 shown in the cross section view 301 may be similar to the exploded view of the corner of the die 200 of FIG. 2A shown in FIG. 2C. In this arrangement, however, an inline pad structure 370 is coupled to the capacitor 360 in the third passivation layer 330 V2. Representatively, portions of the inline pad structure 370 may extend into the dicing street 222 at the Kerf area at the die edge shown in FIG. 2C to enable testing of the passive devices of the die 300.

The overhead view 352 shown in FIG. 3B further illustrates the inline pad structure 370 relative to negative passivation layer masks corresponding to the first passivation layer 350 VP, the second passivation layer 340 V3, and the third passivation layer 330 V2, according to aspects of the present disclosure. Representatively, the inline pad structure 370 includes a first portion 372 and a second portion 374 coupled to the capacitor 360. In this arrangement, the capacitor 360 includes a first capacitor 362 and a second capacitor 364 coupled in series by a shared first plate (e.g., a first conductive interconnect layer (M1). The first capacitor 362 and the second capacitor 364 may be arranged as lateral capacitors. Although FIG. 3B shows a pair of series coupled capacitors, other arrangements including additional series coupled capacitors are possible to suppress any second or third order harmonics caused by any non-linearity of the capacitors.

In this configuration, the first portion 372 of the inline pad structure 370 is coupled to a second plate (e.g., a second conductive interconnect layer M2) of the first capacitor 362 through a first via (e.g., VIA of FIG. 3A). In addition, the second portion 374 of the inline pad structure 370 is coupled to a second plate M2 of the second capacitor 364 through a second via (e.g., VIA of FIG. 3A). The plates of the first capacitor 362 and the second capacitor 364 may be coupled together through a dielectric layer 366 (FIG. 3A). In addition, the first portion 372 and the second portion 374 of the inline pad structure 370 may be composed of a second conductive interconnect layer (M2), and/or a third conductive interconnect layer (M3). In this arrangement, the first portion 372 and the second portion 374 of the inline pad structure 370 may be composed of a first conductive layer (e.g., M1) or a combination of a second conductive layer (e.g., M2), and a third conductive layer (e.g., M3). In this arrangement, the first portion 372 and the second portion 374 of the inline pad structure 370 are covered by the second passivation layer 340 V3, as shown in FIG. 3A.

During testing of the first capacitor 362 and the second capacitor 364, the first portion 372 and the second portion 374 of the inline pad structure 370 are initially uncovered. Once testing of the first capacitor 362 and the second capacitor 364 is complete, the first portion 372 and the second portion 374 of the inline pad structure 370 extending into the Kerf area may be severed during conventional saw dicing. For laser dicing, however, the first portion 372 and the second portion 374 of the inline pad structure 370 remain intact, proximate the Kerf area. Following testing, the first portion 372 and the second portion 374 are covered by the second passivation layer 340 V3, but remain visible toward the edge of the glass substrate 302. Although shown as three passivation layers, the die 300 is not limited to this arrangement and may include any arrangement with multiple passivation layers that are deposited during different stages of die fabrication. The passivation layers may be composed of polyimide or other like dielectric material.

FIGS. 4A and 4B show a cross section view and an overhead view of a capacitor coupled to an inline pad structure at an edge of a die and extending into a dicing street toward the edge of the die, according to another aspect of the present disclosure.

As shown in the cross section view 401 of FIG. 4A, a radio frequency (RF) integrated circuit is composed of a die 400 that includes a glass substrate 402, which supports multiple passivation (e.g., dielectric) layers and a capacitor 460. As shown in the cross section view 401, a first passivation layer 450 (VP) is supported by a second passivation layer 440 (V3) that is supported by a third passivation layer 430 (V2). The die 400 shown in the cross section view 401 may be similar to the exploded view of the corner of the die 200 of FIG. 2A, as shown in FIG. 2C. In this arrangement, however, an inline pad structure 470 is coupled to the capacitor 460 surrounded by the third passivation layer 430 V2. Representatively, portions of the inline pad structure 470 may extend into the dicing street 222 of the Kerf area at the die edge shown in FIG. 2C for testing of the passive devices of the die 400.

The overhead view 452 shown in FIG. 4B further illustrates the inline pad structure 470 relative to negative passivation layer masks corresponding to the first passivation layer 450 VP, the second passivation layer 440 V3, and the third passivation layer 430 V2 according to aspects of the present disclosure. Representatively, the inline pad structure 470 includes a first portion 472 and a second portion 474 coupled to the capacitor 460. In this arrangement, the capacitor 460 includes a first capacitor 462 and a second capacitor 464 coupled in series by the third conductive interconnect layer M3 through first and second vias (e.g., VIA of FIG. 4A). Although FIG. 4B shows a pair of lateral capacitors coupled in series, other arrangements including additional series coupled capacitors are possible, according to aspects of the present disclosure, for suppressing any second or third order harmonics caused by any non-linearity of the capacitors.

In this configuration, the first portion 472 of the inline pad structure 470 is composed of an extension of a first plate (e.g., M1) of the first capacitor 462. The first capacitor 462 also includes a second plate (e.g., M2) coupled to the first plate M1 of the first capacitor 462 through a dielectric layer 466 (FIG. 4A). In addition, the second portion 474 of the inline pad structure 470 is also composed of an extension of a first plate (e.g., M1) of the second capacitor 464. The second capacitor 464 also includes a second plate (e.g., M2) coupled to the first plate M1 of the second capacitor 464 through the dielectric layer 466 (FIG. 4A). In this arrangement, first portion 472 and the second portion 474 of the inline pad structure 470 are covered by the second passivation layer 440 V3, as shown in FIG. 4A, and arranged directly on the glass substrate 402.

During testing of the first capacitor 462 and the second capacitor 464, the first portion 472 and the second portion 474 of the inline pad structure 470 may be initially uncovered. Once testing of the first capacitor 462 and the second capacitor 464 is complete, sections of the first portion 472 and the second portion 474 of the inline pad structure 470 extending into the Kerf area may be severed, assuming conventional saw dicing. With laser dicing, however, the first portion 472 and the second portion 474 of the inline pad structure 470 remain intact after dicing, and are subsequently covered by the second passivation layer 440 V3, but may remain visible at the edge of the die 400. Although shown as three passivation layers, the die 400 is not limited to this arrangement and may include any arrangement including multiple passivation layers that are deposited during different stages of die fabrication. The passivation layers may be composed of polyimide or other like dielectric material.

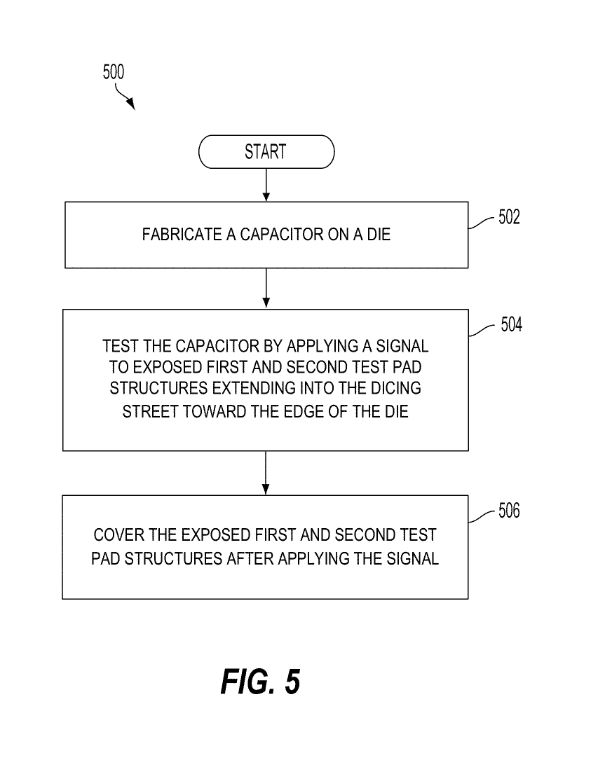

FIG. 5 is a process flow diagram illustrating a method 500 for making and inline testing of a radio frequency (RF) integrated circuit on a die having an edge adjacent to a dicing street according to an aspect of the present disclosure. In block 502, a capacitor is fabricated on a die. For example, as shown in FIGS. 3A and 4A, the capacitor 360/460 may be fabricated on the glass substrate 302/402 of the die 300/400. In block 504, the capacitor is tested by applying a signal to exposed first and second test pad structures extending into the dicing street toward the edge of the die. For example, as shown in FIGS. 2C to 4B, the inline pad structure 370/470 includes a first portion 372/472 and a second portion 374/474 proximate the dicing street 222 at the edge of the glass substrate 402.

Referring again to FIG. 5, in block 506, the exposed first and second test pad structures are covered after applying the signal. For example, as shown in the layout view 301/401 of FIGS. 3A and 4A, the second passivation layer 340/440 V3 covers the inline pad structure 370/470. The applied signal may be a low frequency signal in a range of 1 kHz to 1 MHz. Alternatively, a direct current (DC) voltage in a range of 1 volt to 20 volts may be applied to the exposed test pad structures, such as the first portion 372/472 and the second portion 374/474 of the inline pad structure 370/470 shown in FIGS. 3B and 4B. Once verified, the capacitor may be coupled in parallel with an inductor (e.g., L11, L21, L22), for example, as shown in FIG. 2B to provide a resonator capacitor (e.g., C12, C22, C23).

According to a further aspect of the present disclosure, an RF integrated circuit including a die having passive components including at least one pair of capacitors covered by a first dielectric layer supported by the die is described. The RF integrated circuit also includes an inline pad structure coupled to the at least one pair of capacitors proximate an edge of the die. The inline pad structure may include means for extending into a dicing street toward the edge of the die and covered by at least a second dielectric layer. The extending means may be the first portion 372 and the second portion 374 of the inline pad structure 370, shown in FIGS. 3A and 3B. Alternatively, the extending means may be the first portion 472 and the second portion 474 of the inline pad structure 470, shown in FIGS. 4A and 4B. In another aspect, the aforementioned means may be any layer, module, or any apparatus configured to perform the functions recited by the aforementioned means.

Testing of passive devices at the die area boundary (e.g., a Kerf area) is difficult as these devices are generally covered by passivation layers due to the circuit topology. Conventional inline testing may damage these passive devices due to high pressure applied to the passive device dielectric during probing. For example, individual device inline testing may damage the dielectric of metal-insulator-metal (MIM) capacitors due to high pressure applied to the capacitors during probing. In addition, providing extended probe pads for testing involves additional die area, which increases cost. Alternatively, full radio frequency (RF) testing is complex, which makes such testing costly and time consuming.

In one aspect of the present disclosure, the Kerf area is used to provide inline testing of the passive devices at the die area boundary. The testing is supported by fabrication of an inline pad structure that is coupled to a passive device (e.g., a MIM capacitor) covered by a first dielectric layer near an edge of a passive substrate supporting the passive device. In this arrangement, the inline pad structure includes a first portion and a second portion extending into a dicing street toward the edge of the passive substrate and covered by at least a second dielectric layer.

FIG. 6 is a schematic diagram of a radio frequency (RF) front end (RFFE) module 600 an RF integrated circuit employing passive on glass devices according to an aspect of the present disclosure. The RF front end module 600 includes power amplifiers 602, duplexer/filters 604, and a radio frequency (RF) switch module 606. The power amplifiers 602 amplify signal(s) to a certain power level for transmission. The duplexer/filters 604 filter the input/output signals according to a variety of different parameters, including frequency, insertion loss, rejection or other like parameters. In addition, the RF switch module 606 may select certain portions of the input signals to pass on to the rest of the RF front end module 600.

The RF front end module 600 also includes tuner circuitry 612 (e.g., first tuner circuitry 612A and second tuner circuitry 612B), a diplexer 619, a capacitor 616, an inductor 618, a ground terminal 615 and an antenna 614. The tuner circuitry 612 (e.g., the first tuner circuitry 612A and the second tuner circuitry 612B) includes components such as a tuner, a portable data entry terminal (PDET), and a house keeping analog to digital converter (HKADC). The tuner circuitry 612 may perform impedance tuning (e.g., a voltage standing wave ratio (VSWR) optimization) for the antenna 614. The RF front end module 600 also includes a passive combiner 108 coupled to a wireless transceiver (WTR) 620. The passive combiner 608 combines the detected power from the first tuner circuitry 612A and the second tuner circuitry 612B. The wireless transceiver 620 processes the information from the passive combiner 108 and provides this information to a modem 630 (e.g., a mobile station modem (MSM)). The modem 630 provides a digital signal to an application processor (AP) 640.

As shown in FIG. 6, the diplexer 619 is between the tuner component of the tuner circuitry 612 and the capacitor 616, the inductor 618, and the antenna 614. The diplexer 619 may be placed between the antenna 614 and the tuner circuitry 612 to provide high system performance from the RF front end module 600 to a chipset including the wireless transceiver 620, the modem 630 and the application processor 640. The diplexer 619 also performs frequency domain multiplexing on both high band frequencies and low band frequencies. After the diplexer 619 performs its frequency multiplexing functions on the input signals, the output of the diplexer 619 is fed to an optional LC (inductor/capacitor) network including the capacitor 616 and the inductor 618. The LC network may provide extra impedance matching components for the antenna 614, when desired. Then a signal with the particular frequency is transmitted or received by the antenna 614. Although a single capacitor and inductor are shown, multiple components are also contemplated.

FIG. 7 is a schematic diagram 700 of a WiFi module 770 including a first diplexer 790-1 and an RF front end module 750 including a second diplexer 790-2 for a chipset 760 to provide carrier aggregation according to an aspect of the present disclosure. The WiFi module 770 includes the first diplexer 790-1 communicably coupling an antenna 792 to a wireless local area network module (e.g., WLAN module 772). The RF front end module 750 includes the second diplexer 790-2 communicably coupling an antenna 794 to the wireless transceiver (WTR) 720 through a duplexer 780. The wireless transceiver 720 and the WLAN module 772 of the WiFi module 770 are coupled to a modem (MSM, e.g., baseband modem) 730 that is powered by a power supply 752 through a power management integrated circuit (PMIC) 756. The chipset 760 also includes capacitors 762 and 764, as well as an inductor(s) 766 to provide signal integrity. The PMIC 756, the modem 730, the wireless transceiver 720, and the WLAN module 772 each include capacitors (e.g., 758, 732, 722, and 774) and operate according to a clock 754. The geometry and arrangement of the various inductor and capacitor components in the chipset 760 may reduce the electromagnetic coupling between the components.

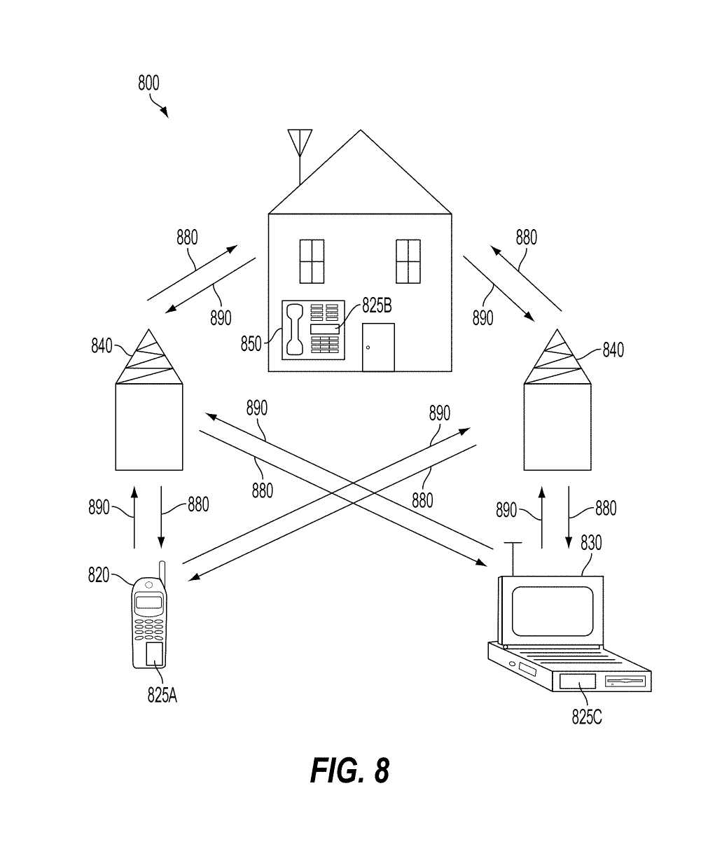

FIG. 8 is a block diagram showing an exemplary wireless communication system 800 in which an aspect of the disclosure may be advantageously employed. For purposes of illustration, FIG. 8 shows three remote units 820, 830, and 850 and two base stations 840. It will be recognized that wireless communication systems may have many more remote units and base stations. Remote units 820, 830, and 850 include IC devices 825A, 825C, and 825B that include the disclosed RF integrated circuit with passive devices. It will be recognized that other devices may also include the disclosed RF integrated circuit and passive devices, such as the base stations, switching devices, and network equipment. FIG. 8 shows forward link signals 880 from the base station 840 to the remote units 820, 830, and 850 and reverse link signals 890 from the remote units 820, 830, and 850 to base stations 840.

In FIG. 8, remote unit 820 is shown as a mobile telephone, remote unit 830 is shown as a portable computer, and remote unit 850 is shown as a fixed location remote unit in a wireless local loop system. For example, a remote units may be a mobile phone, a hand-held personal communication systems (PCS) unit, a portable data unit such as a personal digital assistant (PDA), a GPS enabled device, a navigation device, a set top box, a music player, a video player, an entertainment unit, a fixed location data unit such as a meter reading equipment, or other communications device that stores or retrieve data or computer instructions, or combinations thereof. Although FIG. 8 illustrates remote units according to the aspects of the disclosure, the disclosure is not limited to these exemplary illustrated units. Aspects of the disclosure may be suitably employed in many devices, which include the disclosed RF integrated circuit with passive devices.

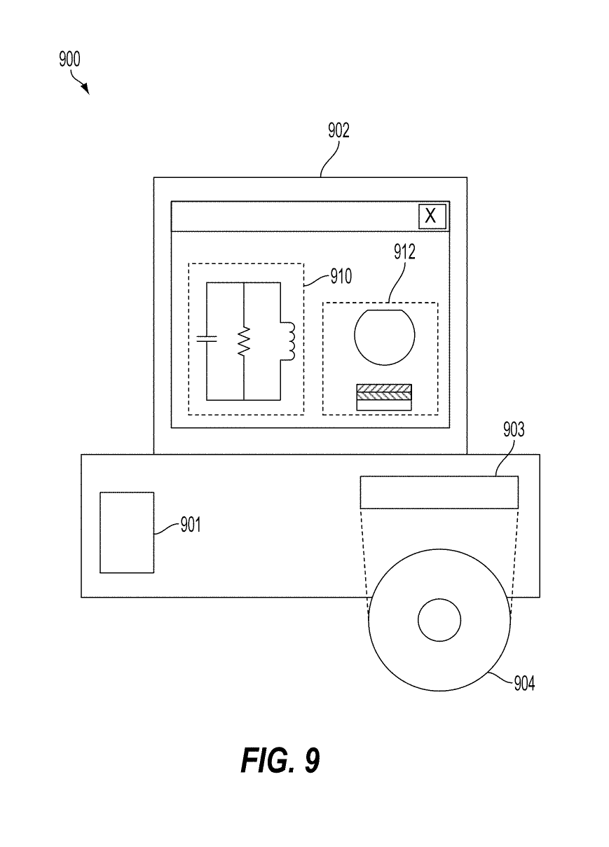

FIG. 9 is a block diagram illustrating a design workstation used for circuit, layout, and logic design of a semiconductor component, such as the RF integrated circuit with passive devices disclosed above. A design workstation 900 includes a hard disk 901 containing operating system software, support files, and design software such as Cadence or OrCAD. The design workstation 900 also includes a display 902 to facilitate design of a circuit 910 or a semiconductor component 912 such as RF integrated circuit with passive devices. A storage medium 904 is provided for tangibly storing the circuit design 910 or the semiconductor component 912. The circuit design 910 or the semiconductor component 912 may be stored on the storage medium 904 in a file format such as GDSII or GERBER. The storage medium 904 may be a CD-ROM, DVD, hard disk, flash memory, or other appropriate device. Furthermore, the design workstation 900 includes a drive apparatus 903 for accepting input from or writing output to the storage medium 904.

Data recorded on the storage medium 904 may specify logic circuit configurations, pattern data for photolithography masks, or mask pattern data for serial write tools such as electron beam lithography. The data may further include logic verification data such as timing diagrams or net circuits associated with logic simulations. Providing data on the storage medium 904 facilitates the design of the circuit design 910 or the semiconductor component 912 by decreasing the number of processes for designing semiconductor wafers.

For a firmware and/or software implementation, the methodologies may be implemented with modules (e.g., procedures, functions, and so on) that perform the functions described herein. Machine-readable medium tangibly embodying instructions may be used in implementing the methodologies described herein. For example, software codes may be stored in a memory and executed by a processor unit. Memory may be implemented within the processor unit or external to the processor unit. As used herein, the term “memory” refers to types of long term, short term, volatile, nonvolatile, or other memory and is not to be limited to a particular type of memory or number of memories, or type of media upon which memory is stored.

If implemented in firmware and/or software, the functions may be stored as one or more instructions or code on a computer-readable medium. Examples include computer-readable media encoded with a data structure and computer-readable media encoded with a computer program. Computer-readable media includes physical computer storage media. A storage medium may be an available medium that can be accessed by a computer. By way of example, and not limitation, such computer-readable media can include RAM, ROM, EEPROM, CD-ROM or other optical disk storage, magnetic disk storage or other magnetic storage devices, or other medium that can be used to store desired program code in the form of instructions or data structures and that can be accessed by a computer; disk and disc, as used herein, includes compact disc (CD), laser disc, optical disc, digital versatile disc (DVD), floppy disk and Blu-ray disc where disks usually reproduce data magnetically, while discs reproduce data optically with lasers. Combinations of the above should also be included within the scope of computer-readable media.

In addition to storage on computer readable medium, instructions and/or data may be provided as signals on transmission media included in a communication apparatus. For example, a communication apparatus may include a transceiver having signals indicative of instructions and data. The instructions and data are configured to cause one or more processors to implement the functions outlined in the claims.

Although the present disclosure and its advantages have been described in detail, it should be understood that various changes, substitutions and alterations can be made herein without departing from the technology of the disclosure as defined by the appended claims. For example, relational terms, such as “above” and “below” are used with respect to a substrate or electronic device. Of course, if the substrate or electronic device is inverted, above becomes below, and vice versa. Additionally, if oriented sideways, above and below may refer to sides of a substrate or electronic device. Moreover, the scope of the present application is not intended to be limited to the particular configurations of the process, machine, manufacture, and composition of matter, means, methods and steps described in the specification. As one of ordinary skill in the art will readily appreciate from the disclosure, processes, machines, manufacture, compositions of matter, means, methods, or steps, presently existing or later to be developed that perform substantially the same function or achieve substantially the same result as the corresponding configurations described herein may be utilized according to the present disclosure. Accordingly, the appended claims are intended to include within their scope such processes, machines, manufacture, compositions of matter, means, methods, or steps.

What is claimed is:

1. A radio frequency (RF) integrated circuit, comprising:
a die comprising a plurality of passive components including at least one pair of capacitors covered by a first dielectric layer supported by the die; and
an inline pad structure coupled to the at least one pair of capacitors proximate an edge of the die, the inline pad structure including a first portion and a second portion extending into a dicing street toward the edge of the die and covered by at least a second dielectric layer.

2. The RF integrated circuit of claim 1, in which the first portion is coupled to a first plate of the at least one pair of capacitors and the second portion is coupled to a second plate of the at least one pair of capacitors.

3. The RF integrated circuit of claim 1, in which the at least one pair of capacitors is coupled in parallel with an inductor.

4. The RF integrated circuit of claim 1, in which the at least one pair of capacitors comprises a pair of series coupled capacitors, each sharing a first plate.

5. The RF integrated circuit of claim 1, in which the first portion and the second portion of the inline pad structure are comprised of a first conductive interconnect layer (M1), a second conductive interconnect layer (M2), and/or a third conductive interconnect layer (M3).

6. The RF integrated circuit of claim 1, integrated into a filter supported by a glass substrate.

7. The RF integrated circuit of claim 6, in which the filter comprises a diplexer, a triplexer, a low pass filter, and/or a notch filter.

8. The RF integrated circuit of claim 6, in which the filter is assembled on a printed circuit board (PCB) of an RF front end module.

9. The RF integrated circuit of claim 1, integrated into an RF front end module, the RF front end module incorporated into at least one of a music player, a video player, an entertainment unit, a navigation device, a communications device, a personal digital assistant (PDA), a fixed location data unit, a mobile phone, and a portable computer.

10. A radio frequency (RF) module, comprising:
a passive die comprising a plurality of passive components including at least one pair of capacitors covered by a first dielectric layer supported by the passive die;
an inline pad structure coupled to the at least one pair of capacitors proximate an edge of the passive die, the inline pad structure including a first portion and a second portion extending into a dicing street toward the edge of the passive die and covered by at least a second dielectric layer; and
an active die coupled to the passive die.

11. The RF module of claim 10, in which the active die is stacked on the passive die or in a side by side arrangement on a package substrate or a lead frame.

12. The RF module of claim 10, in which the first portion is coupled to a first plate of the at least one pair of capacitors and the second portion is coupled to a second plate of the at least one pair of capacitors.

13. The RF module of claim 10, in which the at least one pair of capacitors is coupled in parallel with an inductor.

14. The RF module of claim 10, in which the at least one pair of capacitors comprises a pair of lateral capacitors, each sharing a first plate.

15. The RF module of claim 10, in which the first portion and the second portion of the inline pad structure are comprised of a first conductive layer or a second conductive layer.

16. The RF module of claim 10, integrated into a filter supported by a glass substrate.

17. The RF module of claim 16, in which the filter comprises a diplexer, a triplexer, a low pass filter, and/or a notch filter.

18. The RF module of claim 16, in which the filter is assembled on a printed circuit board (PCB) of the RF module.

19. The RF module of claim 10, integrated into at least one of a music player, a video player, an entertainment unit, a navigation device, a communications device, a personal digital assistant (PDA), a fixed location data unit, a mobile phone, and a portable computer.

20. A method for making and inline testing a radio frequency (RF) integrated circuit on a die having an edge adjacent to a dicing street, comprising:
fabricating a pair of capacitors on the die;
testing the pair of capacitors by applying a signal to exposed first and second test pad structures extending into the dicing street toward the edge of the die;
covering the exposed first and second test pad structures after applying the signal.

21. The method of claim 20, further comprising fabricating an inductor coupled in parallel to the pair of capacitors.

22. The method of claim 20, in which the signal comprises a low frequency signal in a range of 1 kHz to 1 MHz.

23. The method of claim 20, in which applying the signal comprises applying a direct current (DC) voltage in a range of 1 volt to 20 volts to the exposed first and second test pad structures.

24. The method of claim 20, further comprising assembling the RF integrated circuit and the die on a printed circuit board (PCB) of an RF front end module.

25. The method of claim 24, further comprising integrating the RF front end module into at least one of a music player, a video player, an entertainment unit, a navigation device, a communications device, a personal digital assistant (PDA), a fixed location data unit, a mobile phone, and a portable computer.

26. A radio frequency (RF) integrated circuit, comprising:
a die comprising a plurality of passive components including at least one pair of capacitors covered by a first dielectric layer supported by the die; and
an inline pad structure coupled to the at least one pair of capacitors proximate an edge of the die, the inline pad structure comprising means for extending into a dicing street toward the edge of the die and covered by at least a second dielectric layer.

27. The RF integrated circuit of claim 26, integrated into a filter supported by a glass substrate.

28. The RF integrated circuit of claim 27, in which the filter comprises a diplexer, a triplexer, a low pass filter, and/or a notch filter.

29. The RF integrated circuit of claim 27, in which the filter is assembled on a printed circuit board (PCB) of an RF front end module.

30. The RF integrated circuit of claim 26, integrated into an RF front end module, the RF front end module incorporated into at least one of a music player, a video player, an entertainment unit, a navigation device, a communications device, a personal digital assistant (PDA), a fixed location data unit, a mobile phone, and a portable computer.
